(19) United States
(12) Patent Application Publication
(10) Pub. No.: US 2014/0374571 A1
(43) Pub. Date: Dec. 25, 2014

(54) SOLID-STATE IMAGING DEVICE

(71) Applicant: Kabushiki Kaisha Toshiba, Minato-ku (JP)

(72) Inventor: Ryuta Okamoto, Yokohama-shi (JP)

(73) Assignee: Kabushiki Kaisha Toshiba, Minato-ku (JP)

(21) Appl. No.: 14/107,152

(22) Filed: Dec. 16, 2013

(30) Foreign Application Priority Data
Jun. 24, 2013 (JP) 2013-131870

(51) Int. Cl. H01L 27/146; H04N 5/335

(52) U.S. Cl. CPC H01L 27/14609; H04N 5/335
USPC 250/208.1

(57) ABSTRACT

According to one embodiment, a solid-state imaging device includes a pixel array unit having pixels in a matrix form to store charge obtained by photoelectric conversion; a reference voltage generation circuit configured to generate a reference voltage based on an inter-terminal voltage of a first capacitor; and a column ADC circuit configured to calculate an AD conversion value of a pixel signal read out from each of the pixels on the basis of a result of comparison between the pixel signal and the reference voltage, the first capacitor comprising:
a first nonlinear capacitance; and a second nonlinear capacitance connected in parallel with the first nonlinear capacitance to have a polarity opposite to that of the first nonlinear capacitance.

### CROSS-REFERENCE TO RELATED APPLICATIONS

This application is based upon and claims the benefit of priority from Japanese Patent Application No. 2013-131870, filed on Jun. 24, 2013; the entire contents of which are incorporated herein by reference.

### FIELD

Embodiments described herein relate generally to a solid-state imaging device.

### BACKGROUND

In the solid-state imaging device, a ramp wave is used as a reference voltage to be compared with a pixel signal, which is read out from a pixel, in order to conduct AD conversion on the pixel signal. For securing linearity between the pixel signal and its AD-converted value, it is necessary to secure linearity of the ramp wave.

### BRIEF DESCRIPTION OF THE DRAWINGS

FIG. 1 is a block diagram illustrating a schematic configuration of a solid-state imaging device according to a first embodiment;

FIG. 2 is a circuit diagram illustrating a configuration example of a pixel in the solid-state imaging device illustrated in FIG. 1;

FIG. 3 is a circuit diagram illustrating a configuration example of a reference voltage generation circuit and a column ADC circuit illustrated in FIG. 1;

FIG. 4 is a timing chart illustrating voltage waveforms in various parts at the time of read operation of the pixel illustrated in FIG. 1;

FIG. 5A is a diagram illustrating individual CV characteristics of nonlinear capacitances illustrated in FIG. 3, FIG. 5B is a diagram illustrating CV characteristics of the nonlinear capacitances illustrated in FIG. 3 after combining, FIG. 5C is a diagram illustrating waveforms of a reference voltage VREF before and after combining of the nonlinear capacitances illustrated in FIG. 3, in a comparative manner, and FIG. 5D is a diagram illustrating count values before and after combining of the nonlinear capacitances illustrated in FIG. 3, in a comparative manner;

FIG. 6A is a circuit diagram illustrating an example of a switching method of a capacitance value of a nonlinear capacitance CA1 illustrated in FIG. 3, FIG. 6B is a circuit diagram illustrating another example of the switching method of the capacitance value of the nonlinear capacitance CA1 illustrated in FIG. 3, and FIG. 6C is a circuit diagram illustrating still another example of the switching method of the capacitance value of the nonlinear capacitance CA1 illustrated in FIG. 3;

FIG. 7 is a sectional view illustrating a configuration example of a capacitor illustrated in FIG. 3; and

FIG. 8 is a block diagram illustrating a schematic configuration of a digital camera to which a solid-state imaging device according to a second embodiment is applied.

### DETAILED DESCRIPTION

According to one embodiment, a pixel array unit, a reference voltage generation circuit, and a column ADC circuit are provided. In the pixel array unit, pixels which store charge obtained by photoelectric conversion are arranged in a matrix form. The reference voltage generation circuit generates a reference voltage based on an inter-terminal voltage of a capacitor. A column ADC circuit calculates an AD conversion value of a pixel signal read out from the pixel on the basis of a result of comparison between the pixel signal and the reference voltage. The capacitor includes a first nonlinear capacitance and a second nonlinear capacitance. The second nonlinear capacitance is connected in parallel with the first nonlinear capacitance to have a polarity opposite to that of the first nonlinear capacitance.

Hereafter, solid-state imaging devices according to embodiments will be described in detail with reference to the accompanying drawings. Note that the present invention is not restricted by these embodiments.

### First Embodiment

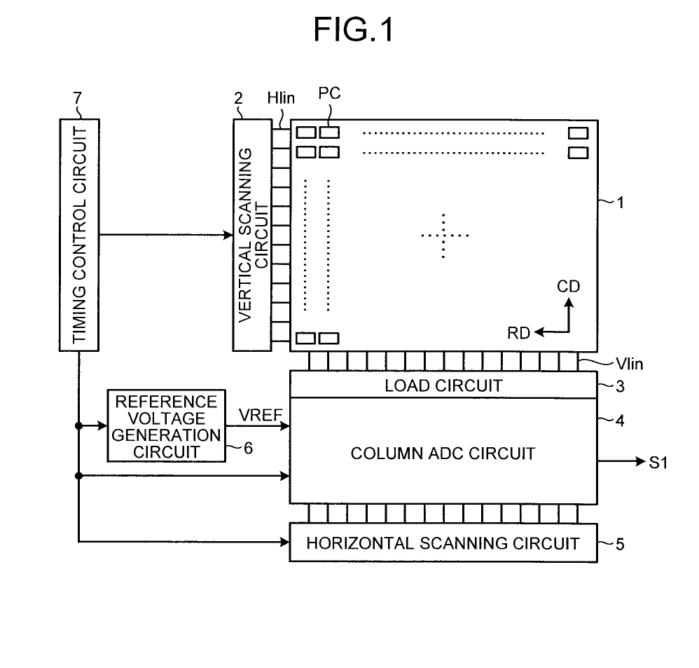

FIG. 1 is a block diagram illustrating a schematic configuration of a solid-state imaging device according to a first embodiment.

In FIG. 1, the solid-state imaging device includes a pixel array unit 1. In the pixel array unit 1, pixels PC which store charge obtained by photoelectric conversion are arranged in a form of a matrix having m (where m is a positive integer) rows in a row direction RD and n (where n is a positive integer) columns in a column direction CD. Furthermore, in the pixel array unit 1, horizontal control lines Hlin are provided in the row direction RD to exercise read control on the pixels PC, and vertical control lines Vlin are provided in the column direction to transmit signals read out from the pixels PC.

The solid-state imaging device further includes a vertical scanning circuit 2 to scan the pixels PC to be read out in the vertical direction, a load circuit 3 to read pixel signals from the pixels PC onto the vertical signal lines Vlin in every column, a column ADC circuit 4 to detect signal components of respective pixels PC in CDS in every column, a horizontal scanning circuit 5 to scan the pixels PC to be read out in the horizontal direction, a reference voltage generation circuit 6 to output a reference voltage VREF to the column ADC circuit 4, and a timing control circuit 7 to control timing of readout from respective pixels PC and storage. Note that a ramp wave can be used as the reference voltage VREF.

Since the vertical scanning circuit 2 scans the pixels PC in the vertical direction, pixels PC are selected in the row direction RD. Then, a source follower operation is conducted between the pixels PC and the load circuit 3. As a result, pixel signals read out from the pixels PC are transmitted via the vertical signal lines Vlin and sent to the column ADC circuit 4. The reference voltage generation circuit 6 sets a ramp wave as the reference voltage VREF, and sends the ramp voltage to the column ADC circuit 4. The column ADC circuit 4 conducts clock count operation until a signal level and a reset level read out from a pixel PC coincide with a level of the ramp wave, detects a signal component of each pixel PC in CDS by finding differences from the signal level and reset level, and outputs the signal component as an output signal S1.

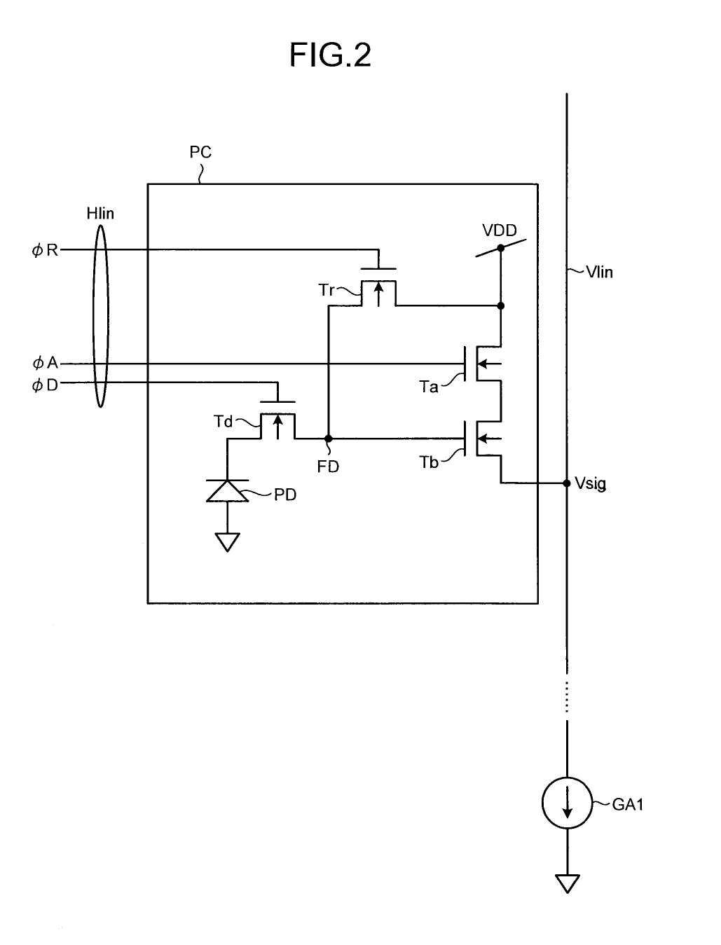

FIG. 2 is a circuit diagram illustrating a configuration example of a pixel in the solid-state imaging device illustrated in FIG. 1.

In FIG. 2, each pixel PC includes a photodiode PD, a row selection transistor Ta, an amplification transistor Tb, a reset transistor Tr, and a read transistor Td. Furthermore, a floating diffusion FD is formed on a connection node of the amplification transistor Tb, the reset transistor Tr, and the read transistor Td as a detection node.

Then, in the pixel PC, a source of the read transistor Td is connected to the photodiode PD, and a read signal ΦD is input to a gate of the read transistor Td. Furthermore, a source of the reset transistor Tr is connected to a drain of the read transistor Td. A reset signal ΦR is input to a gate of the reset transistor Tr. A drain of the reset transistor Tr is connected to a power supply potential VDD. A row selection signal ΦA is input to a gate of the row selection transistor Ta. A drain of the row selection transistor Ta is connected to the power supply potential VDD. Furthermore, a source of the amplification transistor Tb is connected to the vertical signal line Vlin. A gate of the amplification transistor Tb is connected to a drain of the read transistor Td. A drain of the amplification transistor Tb is connected to a source of the row selection transistor Ta. Note that the horizontal control line Hlin illustrated in FIG. 1 can transmit the read signal ΦD, the reset signal ΦR, and the row selection signal ΦA to the pixels PC in every row. The load circuit 3 illustrated in FIG. 1 includes a constant current source GA1 in every column. The constant current source GA1 is connected to the vertical signal line Vlin.

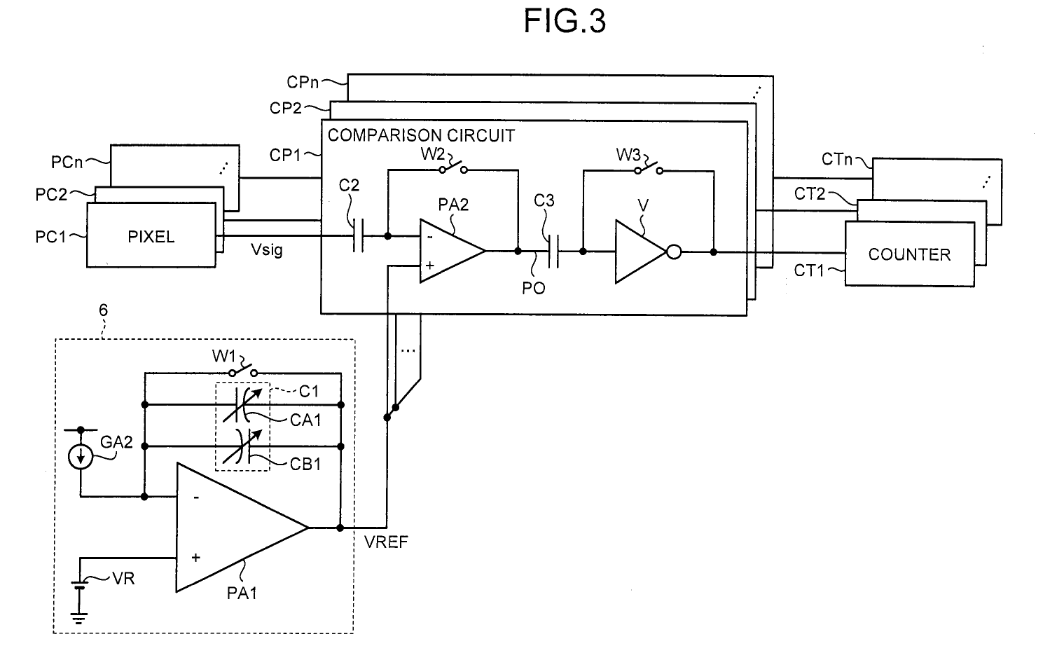

FIG. 3 is a circuit diagram illustrating a configuration example of the reference voltage generation circuit and the column ADC circuit illustrated in FIG. 1.

In FIG. 3, the reference voltage generation circuit 6 includes an operational amplifier PA1, a capacitor C1, a switch W1, a constant current source GA2, and a reference power supply VR. The capacitor C1 includes nonlinear capacitances CA1 and CB1. The nonlinear capacitances CA1 and CB1 are connected in parallel to have opposite polarities each other. In other words, a positive pole of the nonlinear capacitance CA1 is connected to a negative pole of the nonlinear capacitance CB1, and a negative pole of the nonlinear capacitance CA1 is connected to a positive pole of the nonlinear capacitance CB1.

The capacitor C1 is connected between an output terminal of the operational amplifier PA1 and an inverting input terminal thereof. The switch W1 is connected in parallel with the capacitor C1. The constant current source GA2 is connected to the inverting input terminal of the operational amplifier PA1. The reference power supply VR is connected to a non-inverting input terminal of the operational amplifier PA1.

If the switch W1 turns off, a current from the constant current source GA2 flows into the nonlinear capacitances CA1 and CB1 and an inter-terminal voltage of the capacitor C1 increases. Then, the operational amplifier PA1 outputs a reference voltage VREF depending upon the inter-terminal voltage of the capacitor C1. Since the inter-terminal voltage of the capacitor C1 can be expressed as integral of the current flowing from the constant current source GA2 into the capacitor C1, a ramp wave can be obtained as the reference voltage VREF. Furthermore, the inter-terminal voltage of the capacitor C1 can be made zero and the output of the operational amplifier PA1 can be reset by turning on the switch W1.

On the other hand, the column ADC circuit 4 includes comparison circuits CP1 to CPn and counters CT1 to CTn in every column. Then, the comparison circuits CP1 to CPn are connected to pixels PC1 to PCn in the first to nth columns, respectively. The comparison circuit CP1 includes capacitors C2 and C3, a comparator PA2, switches W2 and W3, and an inverter V.

The vertical signal line Vlin is connected to an inverting input terminal of the comparator PA2 via the capacitor C2. The output terminal of the operational amplifier PA1 is connected to a non-inverting input terminal of the comparator PA2. The switch W2 is connected between the inverting input terminal and an output terminal of the comparator PA2. The output terminal of the comparator PA2 is connected to an input terminal of the inverter V via the capacitor C3. The counter CT1 is connected to an output terminal of the inverter V. The switch W3 is connected between the input terminal and the output terminal of the inverter V.

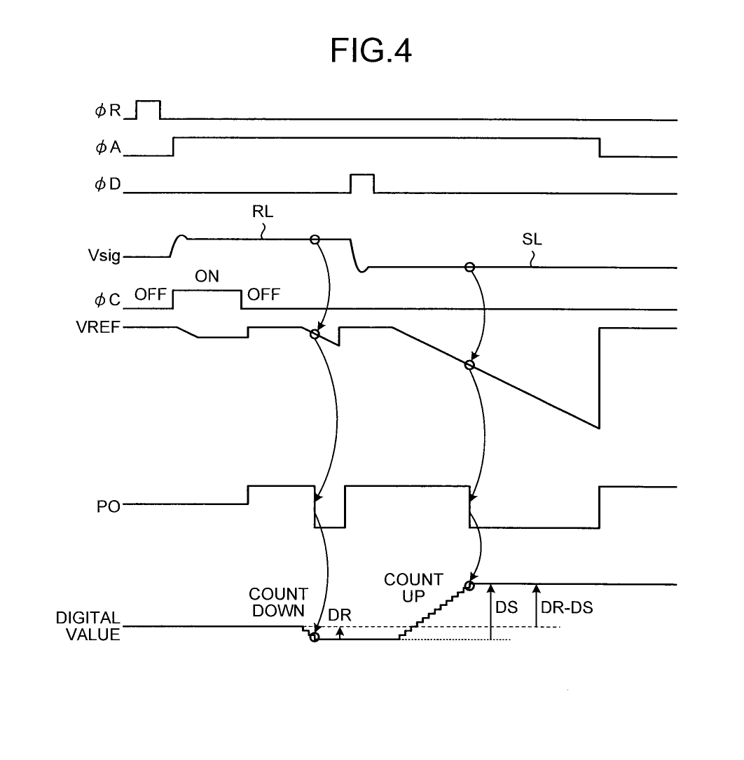

FIG. 4 is a timing chart illustrating voltage waveforms in various parts at the time of read operation of the pixel illustrated in FIG. 1.

If the row selection signal ΦA is at a low level in FIG. 4, the row selection transistor Ta turns off and the source follower operation is not conducted, and consequently a signal is not output to the vertical signal line Vlin. If the read signal ΦD and the reset signal ΦR become the high level at this time, the read transistor Td turns on and charge stored in the photodiode PD is exhausted to the floating diffusion FD. Then, the charge is exhausted to the power supply potential VDD via the reset transistor Tr.

When the read signal ΦD becomes the low level after the charge stored in the photodiode PD is exhausted to the power supply potential VDD, the photodiode PD starts storage of effective signal charge.

When the reset signal ΦD rises subsequently, the reset transistor Tr turns on and resets extra charge generated in the floating diffusion FD by a leak current or the like.

When the row selection signal ΦA becomes the high level, the row selection transistor Ta in the pixel PC turns on and the power supply potential VDD is applied to the drain of the amplification transistor Tb. As a result, the amplification transistor Tb and the constant current source GA1 constitute a source follower. Then, a voltage depending upon a reset level RL of the floating diffusion FD is applied to the gate of the amplification transistor Tb. Since the amplification transistor Tb and the constant current source GA1 constitute a source follower, a voltage on the vertical signal line Vlin follows the voltage applied to the gate of the amplification transistor Tb. Then, a pixel signal Vsig of the reset level RL is output to the column ADC circuit 4 via the vertical signal line Vlin.

When the pixel signal Vsig of the reset level RL is output onto the vertical signal line Vlin, a reset pulse TC is applied to the switch W2. When the switch W2 turns on, an input voltage at the inverting input terminal of the comparator PA2 is clamped by an output voltage PO and an operating point is set. At this time, charge depending upon a difference voltage from the pixel signal Vsig supplied from the vertical signal line Vlin is retained by the capacitor C2 and the input voltage of the comparator PA2 is set equal to zero. The reset pulse ΦC is applied to the switch W3. When the switch W3 turns on, an input voltage at the input terminal of the inverter V is clamped by an output voltage and an operating point is set. At this time, charge depending upon a difference voltage from an output signal of the inverter V is retained by the capacitor C3 and the input voltage of the inverter V is set equal to zero.

After the switches W2 and W3 turn off, the ramp wave is supplied as the reference voltage VREF in a state in which the pixel signal Vsig of the reset level RL is input to the comparator PA2 via the capacitor C2. As a result, the pixel signal Vsig of the reset level RL is compared with the reference voltage VREF. The output voltage PO of the comparator PA2 is inverted by the inverter V, and then a resultant signal is input to the counter CT1.

The counter CT1 down-counts until the pixel signal Vsig of the reset level RL coincides with a level of the reference voltage VREF. As a result, the pixel signal Vsig of the reset level RL is converted to a digital value DR and retained.

Next, when the read signal ΦD rises, the read transistor Td turns on, and the charge stored in the photodiode PD is transferred to the floating diffusion FD. A voltage depending upon a signal level SL of the floating diffusion FD is applied to the gate of the amplification transistor Tb. Since the amplification transistor Tb and the constant current source GA1 constitute the source follower, the voltage on the vertical signal line Vlin follows the voltage applied to the gate of the amplification transistor Tb. Then, the pixel signal Vsig of the signal level SL is output to the column ADC circuit 4 via the vertical signal line Vlin.

In the column ADC circuit 4, the ramp wave is supplied as the reference voltage VREF in a state in which the pixel signal Vsig of the signal level SL is input to the comparator PA2 via the capacitor C2. As a result, the pixel signal Vsig of the signal level SL is compared with the reference voltage VREF. The output voltage PO of the comparator PA2 is inverted by the inverter V, and then a resultant signal is input to the counter CT1.

This time, the counter CT1 up-counts until the pixel signal Vsig of the signal level SL coincides with a level of the reference voltage VREF. As a result, the pixel signal Vsig of the signal level SL is converted to a digital value DS. A difference DR-DS between the pixel signal Vsig of the reset level RL and the pixel signal Vsig of the signal level SL is retained by the counter CT1 and output as an output signal S1.

The flatness of CV characteristics of the capacitor C1 can be improved by constituting the capacitor C1 using the nonlinear capacitances CA1 and CB1 connected in parallel to have opposite polarities each other. As a result, linearity of the ramp wave to be compared with the pixel signal Vsig can be improved, and linearity of AD conversion characteristics of the counter CT1 can be improved.

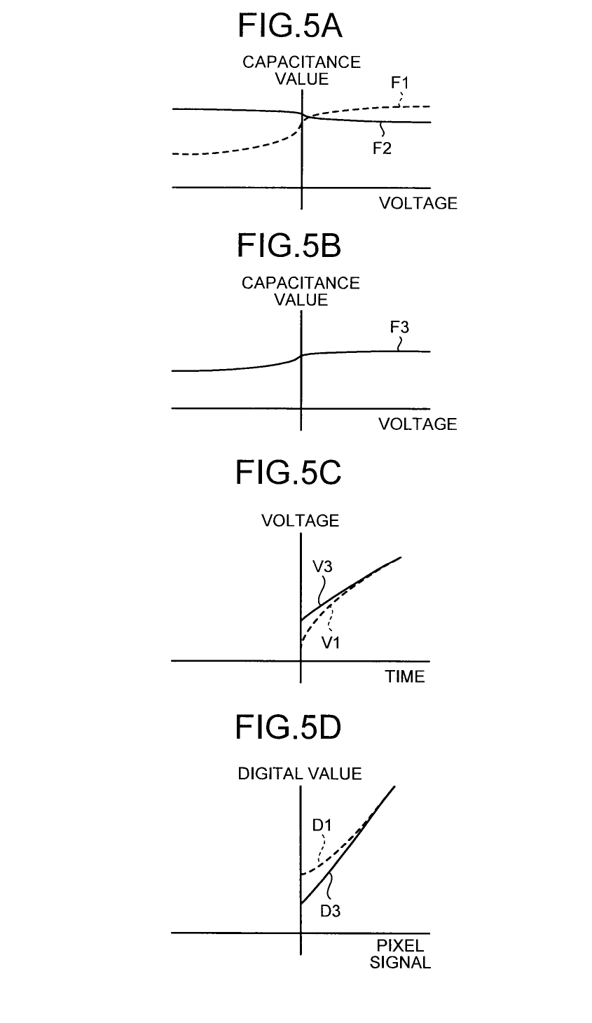

FIG. 5A is a diagram illustrating individual CV characteristics of nonlinear capacitances illustrated in FIG. 3. FIG. 5B is a diagram illustrating CV characteristics of the nonlinear capacitances illustrated in FIG. 3 after combining. FIG. 5C is a diagram illustrating waveforms of a reference voltage VREF before and after combining of the nonlinear capacitances illustrated in FIG. 3, in a comparative manner. FIG. 5D is a diagram illustrating count values before and after combining of the nonlinear capacitances illustrated in FIG. 3, in a comparative manner.

In FIG. 5A, the nonlinear capacitance CA1 has CV characteristics F1. As the inter-terminal voltage increases, the capacitance value increases. If the capacitor C1 is constituted by using only the nonlinear capacitance CA1, therefore, the reference voltage VREF has VT characteristics V1 as illustrated in FIG. 5C and linearity of the reference voltage VREF falls. As illustrated in FIG. 5D, therefore, the counter CT1 has AD conversion characteristics D1, and linearity of the digital values DR and DS generated by the counter CT1 falls.

On the other hand, in FIG. 5A, the nonlinear capacitance CB1 has CV characteristics F2, and the capacitance value decreases as the inter-terminal voltage increases. As illustrated in FIG. 5B, therefore, the capacitance C1 can be provided with CV characteristics F3 and flatness of CV characteristics of the capacitor C1 can be improved by constituting the capacitor C1 using the nonlinear capacitances CA1 and CB1 connected in parallel to have opposite polarities each other. As a result, the reference voltage VREF can be provided with VT characteristics V3 as illustrated in FIG. 5C and the linearity of the reference voltage VREF can be improved. As illustrated in FIG. 5D, therefore, the counter CT1 can be provided with AD conversion characteristics D3 and the linearity of the digital values DR and DS generated by the counter CT1 can be improved.

Note that the nonlinear capacitances CA1 and CB1 may also be used as variable capacitances. As a result, the CV characteristics of the capacitor C1 can be adjusted while considering not only the CV characteristics of the capacitor C1 but also output characteristics of the operational amplifier PA1 and the constant current source GA2, and linearity of the VT characteristics V3 of the reference voltage VREF can be further improved.

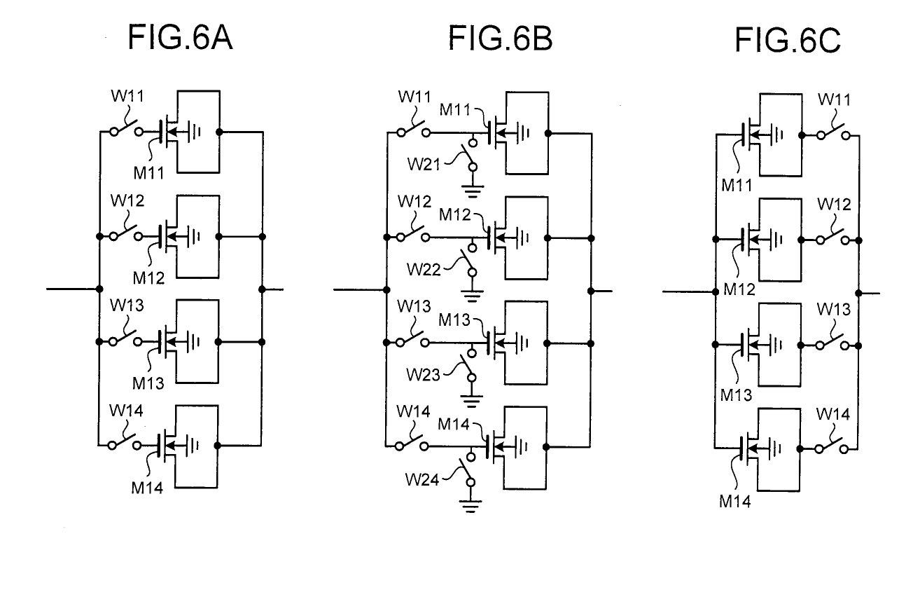

FIG. 6A is a circuit diagram illustrating an example of a switching method of a capacitance value of a nonlinear capacitance CA1 illustrated in FIG. 3. FIG. 6B is a circuit diagram illustrating another example of the switching method of the capacitance value of the nonlinear capacitance CA1 illustrated in FIG. 3. FIG. 6C is a circuit diagram illustrating still another example of the switching method of the capacitance value of the nonlinear capacitance CA1 illustrated in FIG. 3.

In FIG. 6A, the nonlinear capacitance CA1 includes N-channel field effect transistors M11 to M14 and switches W11 to W14. Gates of the N-channel field effect transistors M11 to M14 are connected to the switches W11 to W14, respectively. A source and a drain of each of the N-channel field effect transistors M11 to M14 are connected in common. Here, each of the N-channel field effect transistors M11 to M14 can constitute a non-variable capacitance.

The N-channel field effect transistors M11 to M14 can be separated by turning off the switches W11 to W14, respectively. It becomes possible to adjust the capacitance value of the nonlinear capacitance CA1 in this way. As a result, the nonlinear capacitance CA1 can be used as a variable capacitance.

Alternatively, as illustrated in FIG. 6B, switches W21 to W24 may be connected between gates of the N-channel field effect transistors M11 to M14 and the ground, respectively, in the configuration illustrated in FIG. 6A. When the switches W11 to W14 are turned off, the switches W21 to W24 are turned on, respectively. As a result, the gates of the N-channel field effect transistors M11 to M14 can be connected to the ground, respectively, while separating the N-channel field effect transistors M11 to M14, respectively.

Alternatively, it is also possible to connect sources and drains of the N-channel field effect transistors M11 to M14 to the switches W11 to W14 in common, respectively and connect the gates of the N-channel field effect transistors M11 to M14 in common, as illustrated in FIG. 6C.

Then, the N-channel field effect transistors M11 to M14 can be separated by turning off the switches W11 to W14. As a result, it becomes possible to adjust the capacitance value of the nonlinear capacitance CA1. Consequently, the nonlinear capacitance CA1 can be used as a variable capacitance.

In the examples illustrated in FIGS. 6A to 6C, a method of providing four N-channel field effect transistors M11 to M14 in the nonlinear capacitance CA1 has been described. However, two, three, or at least five N-channel field effect transistors may be provided in the nonlinear capacitance CA1. Furthermore, in the examples illustrated in FIGS. 6A to 6C, a method of providing N-channel field effect transistors in the nonlinear capacitance CA1 has been described. However, P-channel field effect transistors may be provided in the nonlinear capacitance CA1, or CMOS transistors may be provided in the nonlinear capacitance CA1. Furthermore, the nonlinear capacitance CB1 can also be constituted in the same way as the nonlinear capacitance CA1.

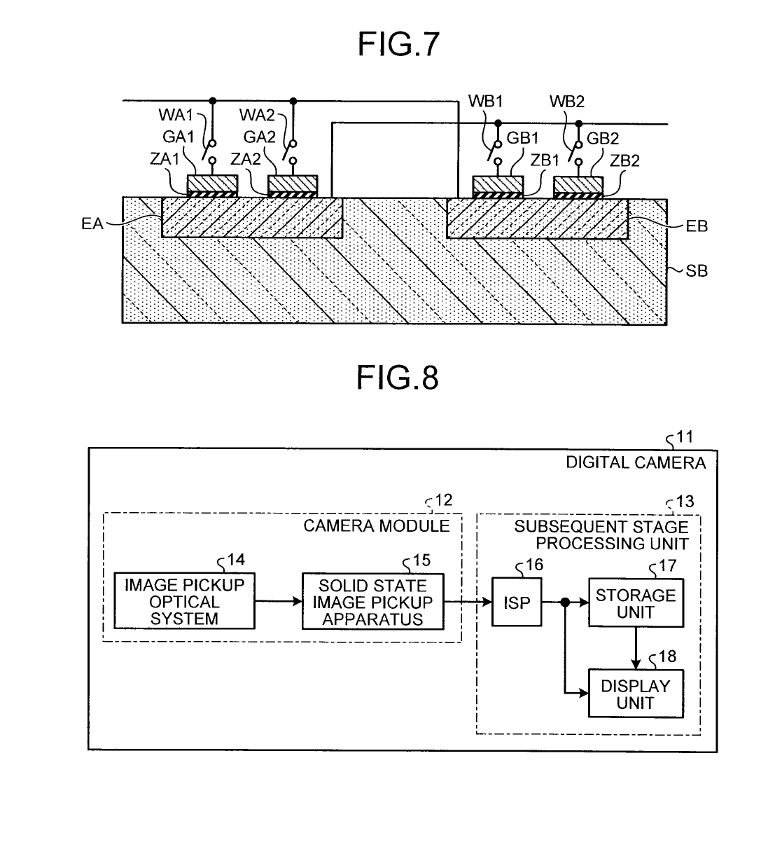

FIG. 7 is a sectional view illustrating a configuration example of a capacitor illustrated in FIG. 3.

In FIG. 7, wells EA and EB are formed in a semiconductor substrate SB. Electrodes GA1 and GA2 are formed over the well EA via gate insulation films ZA1 and ZA2, respectively. Electrodes GB1 and GB2 are formed over the well EB via gate insulation films ZB1 and ZB2, respectively. Note that the electrodes GA1 and GA2 can constitute a positive electrode of the nonlinear capacitance CA1, and the well EA can constitute a negative electrode of the nonlinear capacitance CA1. The electrodes GB1 and GB2 can constitute a positive electrode of the nonlinear capacitance CB1, and the well EB can constitute a negative electrode of the nonlinear capacitance CB1.

The electrodes GA1 and GA1 are connected to the inverting input terminal of the operational amplifier PA1 illustrated in FIG. 3 via switches WA1 and WA2, respectively. Furthermore, the well EB is connected to the inverting input terminal of the operational amplifier PA1. The electrodes GB1 and GB2 are connected to the output terminal of the operational amplifier PA1 illustrated in FIG. 3 via switches WB1 and WB2, respectively. Furthermore, the well EA is connected to the output terminal of the operational amplifier PA1.

Then, the electrodes GA1, GA2, GB1 and GB2 can be separated by turning off the switches WA1, WA2, WB1 and WB2, respectively. It becomes possible to adjust the capacitance values of the nonlinear capacitances CA1 and CB1 in this way. Furthermore, it becomes possible to integrate the nonlinear capacitances CA1 and CB1 together with the operational amplifier PA1 by forming the nonlinear capacitances CA1 and CB1 on the semiconductor substrate SB.

Note that in the example illustrated in FIG. 7, a method of providing the two electrodes GA1 and GA2 in the nonlinear capacitance CA1 and providing the two electrodes GB1 and GB2 in the nonlinear capacitance CB1 has been described. However, at least three electrodes and switches may be provided in each of the nonlinear capacitances CA1 and CB1.

### Second Embodiment

FIG. 8 is a block diagram illustrating a schematic configuration of a digital camera to which a solid-state imaging device according to a second embodiment is applied.

In FIG. 8, a digital camera 11 includes a camera module 12 and a subsequent stage processing unit 13. The camera module 12 includes an image pickup optical system 14 and a solid-state imaging device 15. The subsequent stage processing unit 13 includes an image signal processor (ISP) 16, a storage unit 17, and a display unit 18. Note that, as for the solid-state imaging device 15, the configuration illustrated in FIG. 1 can be used. Furthermore, a configuration of at least a part of the ISP 16 may be formed as one chip together with the solid-state imaging device 15.

The image pickup optical system 14 takes in light from an object and forms an image of the object. The solid-state imaging device 15 picks up the object image. The ISP 16 conducts signal processing on an image signal obtained by the image pickup in the solid-state imaging device 15. The storage unit 17 stores an image subjected to the signal processing in the ISP 16. The storage unit 17 outputs the image signal to the display unit 18 in accordance with a user's operation. The display unit 18 displays an image in accordance with an image signal which is input from the ISP 16 or the storage unit 17. The display unit 18 is, for example, a liquid crystal display. Note that the camera module 12 may be applied to an electronic device such as, for example, a portable terminal having a camera, besides the digital camera 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a pixel array unit having pixels in a matrix form to store charge obtained by photoelectric conversion;
a reference voltage generation circuit configured to generate a reference voltage based on an inter-terminal voltage of a first capacitor; and
a column ADC circuit configured to calculate an AD conversion value of a pixel signal read out from each of the pixels on the basis of a result of comparison between the pixel signal and the reference voltage,
the first capacitor comprising:
a first nonlinear capacitance; and
a second nonlinear capacitance connected in parallel with the first nonlinear capacitance to have a polarity opposite to that of the first nonlinear capacitance.

2. The solid-state imaging device according to claim 1, wherein
the reference voltage generation circuit comprises:
an operational amplifier; and
a constant current source connected to an inverting input terminal of the operational amplifier,
the first nonlinear capacitance is connected between an output terminal and the inverting input terminal of the operational amplifier, and
the second nonlinear capacitance is connected between the output terminal and the inverting input terminal of the operational amplifier to have a polarity opposite to that of the first nonlinear capacitance.

3. The solid-state imaging device according to claim 1, wherein capacitance values of the first nonlinear capacitance and the second nonlinear capacitance are set to improve flatness of CV characteristics of the first capacitor.

4. The solid-state imaging device according to claim 1, wherein at least one of the first nonlinear capacitance and the second nonlinear capacitance is a variable capacitance.

5. The solid-state imaging device according to claim 4, wherein the variable capacitance comprises:
a plurality of non-variable capacitances; and
switches configured to separate a non-variable capacitance selected out of the plurality of non-variable capacitances.

6. The solid-state imaging device according to claim 5, wherein the non-variable capacitance is a field effect transistor having a source and a drain connected in common.

7. The solid-state imaging device according to claim 6, wherein a gate of the field effect transistor is connected to one of the switches.

8. The solid-state imaging device according to claim 2, wherein
the first nonlinear capacitance comprises:
a first well formed in a semiconductor substrate; and
a first electrode formed over the first well via a gate insulation film,
the second nonlinear capacitance comprises:
a second well formed in the semiconductor substrate; and
a second electrode formed over the second well via the gate insulation film,
the first well constitutes a positive electrode of the first nonlinear capacitance, and the first electrode constitutes a negative electrode of the first nonlinear capacitance, and
the second well constitutes a negative electrode of the second nonlinear capacitance, and the second electrode constitutes a positive electrode of the second nonlinear capacitance.

9. The solid-state imaging device according to claim 8, wherein the first well is connected to the output terminal of the operational amplifier, the first electrode is connected to the inverting input terminal of the operational amplifier, the second well is connected to the inverting input terminal of the operational amplifier, and the second electrode is connected to the output terminal of the operational amplifier.

10. The solid-state imaging device according to claim 1, wherein each of the pixels comprises:
a photodiode configured to conduct photoelectric conversion;
a read transistor configured to transfer a signal from the photodiode to a floating diffusion;
a reset transistor configured to reset a signal stored in the floating diffusion; and
an amplification transistor configured to detect a potential at the floating diffusion.

11. The solid-state imaging device according to claim 1, comprising:
a vertical scanning circuit configured to scan the pixels in a vertical direction;
a load circuit configured to read pixel signals from the pixels onto vertical signal lines in every column by conducting a source follower operation between the pixels and the load circuit; and
a horizontal scanning circuit configured to scan the pixels in a horizontal direction.

12. The solid-state imaging device according to claim 2, wherein the reference voltage is the inter-terminal voltage of the first capacitor generated depending upon a current flowing from the constant current source into the first capacitor.

13. The solid-state imaging device according to claim 12, wherein the inter-terminal voltage of the first capacitor is given by integral of the current flowing from the constant current source into the first capacitor.

14. The solid-state imaging device according to claim 13, wherein the reference voltage generation circuit comprises a switch configured to reset an output of the operational amplifier by making the inter-terminal voltage of the first capacitor equal to zero.

15. The solid-state imaging device according to claim 11, wherein the column ADC circuit comprises:
a comparison circuit configured to compare each of the pixel signals read out from the pixels with the reference voltage; and
a counter configured to conduct a count operation until the pixel signal coincides with a level of the reference voltage.

16. The solid-state imaging device according to claim 15, wherein
the comparison circuit comprises:
a comparator; and
a switch,
an inverting input terminal of the comparator is connected to one of the vertical signal lines via a second capacitor, a non-inverting input terminal of the comparator is connected to the output terminal of an operational amplifier, and the switch is connected between the inverting input terminal and an output terminal of the comparator.

17. The solid-state imaging device according to claim 16, wherein the switch turns on when the pixel signal is output to the vertical signal line, and consequently charge depending upon a difference voltage from the pixel signal supplied from the vertical signal line is retained by the second capacitor, and an input voltage of the comparator is set equal to zero.

18. The solid-state imaging device according to claim 1, wherein nonlinearity of the first nonlinear capacitance is canceled by nonlinearity of the second nonlinear capacitance.

19. The solid-state imaging device according to claim 18, wherein a capacitance value of the first nonlinear capacitance decreases as an inter-terminal voltage of the first nonlinear capacitance increases, and a capacitance value of the second nonlinear capacitance increases as an inter-terminal voltage of the second nonlinear capacitance increases.

20. The solid-state imaging device according to claim 2, wherein the first capacitor is integrated on same semiconductor substrate together with the operational amplifier.
